(19) United States
(12) Patent Application Publication
(10) Pub. No.: US 2026/0099178 A1
(43) Pub. Date: Apr. 9, 2026

(54) REFLECTING SURFACE ASSEMBLY, DISPLAY PANEL, AND WIRELESS COMMUNICATION APPARATUS

(71) Applicant: Yungu (Gu’an) Technology Co., Ltd., Langfang (CN)

(72) Inventors: Huan-Chu HUANG, Taiwan (CN); Jie WU, Langfang (CN); Shuang CUI, Langfang (CN); Haijing SHEN, Langfang (CN); Jiahe LIANG, Langfang (CN)

(73) Assignee: Yungu (Gu’an) Technology Co., Ltd., Langfang (CN)

(21) Appl. No.: 19/417,253

(22) Filed: Dec. 11, 2025

Related U.S. Application Data
(63) Continuation of application No. PCT/CN2023/134172, filed on Nov. 24, 2023.

(30) Foreign Application Priority Data
Jun. 13, 2023 (CN) 202310699517.3

(51) Int. Cl. G06F 1/18; G06F 1/184; H10H 29/49

(52) U.S. Cl. CPC G06F 1/182; G06F 1/184; H10H 29/49

(57) ABSTRACT

Embodiments of the present application provide a reflecting surface assembly, a display panel, and a wireless communication apparatus. The display panel includes: a substrate; and a reflecting surface assembly provided on the substrate, the reflecting surface assembly including a functional layer and a shielding layer, the functional layer including a reflecting unit configured to reflect a wireless signal, and the shielding layer being provided on a side of the functional layer facing the substrate, where the reflecting unit has a connection line connected thereto such that the reflecting unit is connectable to a control circuit through the connection line, and the control circuit is configured to change an electrical load of the reflecting unit. In the embodiments of the present application, providing the reflecting surface assembly with high light transmittance in the display panel can effectively improve the wireless communication performance of the display panel.

### CROSS-REFERENCE TO RELATED APPLICATIONS

The present application is a continuation of International Application No. PCT/CN2023/134172 filed on Nov. 24, 2023, which claims priority to Chinese Patent Application No. 202310699517.3, entitled “REFLECTING SURFACE ASSEMBLY, DISPLAY PANEL, AND WIRELESS COMMUNICATION APPARATUS” and filed on Jun. 13, 2023, which are incorporated herein by reference in their entireties.

### FIELD

The present application relates to the field of display devices, and in particular, to a reflecting surface assembly, a display panel, and a wireless communication apparatus.

### BACKGROUND

Wireless communication apparatuses (such as mobile phones and smart watches) are rapidly evolving in functionality, while there are increasingly high requirements for the appearance and wireless communication performance of the apparatuses on the market. How to improve the communication performance of wireless communication apparatuses thus has become an urgent problem to be resolved.

### SUMMARY

Embodiments of the present application provide a reflecting surface assembly, a display panel, and a wireless communication apparatus, which are intended to improve the communication performance of the display panel.

An embodiment of a first aspect of the present application provides a display panel. The display panel includes: a substrate; and a reflecting surface assembly provided on the substrate, the reflecting surface assembly including a functional layer and a shielding layer, the functional layer including at least a reflecting unit configured to reflect wireless signals, and the shielding layer being provided on a side of the functional layer facing the substrate, where the reflecting unit has a connection line connected thereto such that the reflecting unit is connectable to a control circuit through the connection line, and the control circuit is configured to change an electrical load of the reflecting unit; and where both the functional layer and the shielding layer are transparent layer structures.

An embodiment of a second aspect of the present application further provides a wireless communication apparatus, including a display panel according to any one of the above embodiments of the first aspect. According to an embodiment in the second aspect of the present application, the wireless communication apparatus further includes a flexible circuit board, where the control circuit is provided on the flexible circuit board, and the flexible circuit board is bent such that the control circuit is located on a non-display side of the display panel.

An embodiment of a third aspect of the present application further provides a reflecting surface assembly, including a functional layer and a shielding layer, the functional layer including at least a reflecting unit configured to reflect wireless signals, and the shielding layer being provided on a side of the functional layer, where the reflecting unit has a connection line connected thereto such that the reflecting unit is connectable to a control circuit through the connection line, and the control circuit is configured to change an electrical load of the reflecting unit; and where both the functional layer and the shielding layer are of a transparent layer structure.

According to the display panel provided in the embodiments of the present application, the display panel includes the substrate and the reflecting surface assembly provided on the substrate. The reflecting surface assembly includes the functional layer, the shielding layer, and the control circuit. The functional layer includes the reflecting unit, and the reflecting unit can reflect the wireless signal, for example, the reflecting unit can reflect the wireless signal to a communication target, to improve the wireless communication quality of the display panel. The shielding layer is provided on the side of the functional layer facing away from a display surface of the display panel, such that the shielding layer can shield the wireless signal to enable the wireless signal to be reflected at the functional layer, and can also reduce the entry of the wireless signal into the display panel that affects normal operation of other parts and components of the display panel. The control circuit is connected to the reflecting unit through the connection line, which can change the electrical load of the reflecting unit. Both the functional layer and the shielding layer are of the transparent layer structure, which can reduce the impact of the reflecting surface assembly on the display effect of the display panel. Therefore, in the embodiments of the present application, providing the reflecting surface assembly with high light transmittance in the display panel can effectively improve the wireless communication performance of the display panel.

### BRIEF DESCRIPTION OF THE DRAWINGS

FIG. 1 is a schematic diagram of a structure of a display panel according to an embodiment of a first aspect of the present application;

FIG. 2 is a schematic partial enlarged view of a structure taken along line A-A in

FIG. 1;

FIG. 3 is a schematic diagram of a structure of a display panel according to another embodiment of the first aspect of the present application;

FIG. 4 is a schematic diagram of a structure of a display panel according to still another embodiment of the first aspect of the present application;

FIG. 5 is a schematic diagram of a structure of a display panel according to yet another embodiment of the first aspect of the present application;

FIG. 6 is a schematic diagram of a structure of a display panel according to still yet another embodiment of the first aspect of the present application;

FIG. 7 is a schematic diagram of a structure of a display panel according to still yet another embodiment of the first aspect of the present application;

FIG. 8 is a schematic diagram of a structure of a display panel according to still yet another embodiment of the first aspect of the present application;

FIG. 9 is a schematic diagram of a structure of a display panel according to still yet another embodiment of the first aspect of the present application;

FIG. 10 is a schematic diagram of a structure of a display panel according to still yet another embodiment of the first aspect of the present application;

FIG. 11 is a schematic diagram of a structure of a display panel according to still yet another embodiment of the first aspect of the present application;

FIG. 12 is a schematic diagram of a structure of a display panel according to still yet another embodiment of the first aspect of the present application;

FIG. 13 is a schematic diagram of a structure of a display panel according to still yet another embodiment of the first aspect of the present application;

FIG. 14 is a cross-sectional view taken along line B-B in FIG. 13;

FIG. 15 is a schematic diagram of a structure of a display panel according to still yet another embodiment of the first aspect of the present application;

FIG. 16 is a schematic diagram of a structure of a display panel according to still yet another embodiment of the first aspect of the present application;

FIG. 17 is a schematic diagram of a structure of a display panel according to still yet another embodiment of the first aspect of the present application;

FIG. 18 is a schematic partial enlarged view of a structure taken along line A-A in FIG. 1 in another embodiment;

FIG. 19 is a schematic diagram of a structure of a wireless communication apparatus according to an embodiment of a second aspect of the present application;

FIG. 20 is a schematic diagram of a structure of a wireless communication apparatus according to another embodiment of the second aspect of the present application;

FIG. 21 is a cross-sectional view taken along line C-C in FIG. 21;

FIG. 22 is a schematic diagram of a structure of a wireless communication apparatus according to still another embodiment of the second aspect of the present application;

FIG. 23 is a schematic diagram of a structure of a wireless communication apparatus according to yet another embodiment of the second aspect of the present application;

FIG. 24 is a cross-sectional view taken along line C-C in FIG. 21 in another embodiment; and

FIG. 25 is a schematic diagram of a structure of a wireless communication apparatus according to another embodiment of the second aspect of the present application.

### DETAILED DESCRIPTION OF THE EMBODIMENTS

With the development of display technologies and wireless communication technologies, there are increasingly high requirements for the communication performance of wireless communication apparatuses. Intelligent reflecting surface (IRS), as an important communication design that has currently attracted extensive attention and research investment, can change the direction and number of reflected beams incident from a wireless signal source by regulating amplitudes and phases of electrical signals on a plurality of reflecting units on the intelligent reflecting surface (i.e., by changing electrical loads of the reflecting units), such as by regulating the reflected beam, which is used as one reflected beam or split into a plurality of reflected beams, to be directed toward one or more communication targets, thereby facilitating a significant improvement in the wireless communication quality. The IRS may be installed on interior or exterior walls of a building.

The IRS is generally a structure of three layers, that is, a reflecting unit on the top layer, which is a conductor structure and is configured to reflect wireless signals; a metal plate, such as a copper plate, below the reflecting unit, which is configured to shield and reflect a wireless signal; and a control circuit board provided on a side of the metal plate facing away from the reflecting unit, with a control circuit on the control circuit board being connected to the reflecting unit and configured to regulate a signal amplitude and phase for each reflecting unit, to control the direction and number of reflected beams. However, since all the three layers in this structure are visually non-transparent to human eyes, the IRS is also visually non-transparent to human eyes.

In order to improve the communication performance of a display panel, the present application enables the IRS to be integrated onto the display panel. However, as mentioned above, current IRSs are primarily designed to be visually non-transparent to human eyes, which may obstruct a background (such as walls) on which they are installed, and compromise the original aesthetic design and consistency of the background, resulting in limited application scenarios and scope of the IRSs.

To resolve the above problem, the present application is provided. In order to better understand the present application, a reflecting surface assembly, a display panel, and a wireless communication apparatus according to embodiments of the present application will be described below in detail with reference to FIG. 1 to FIG. 24.

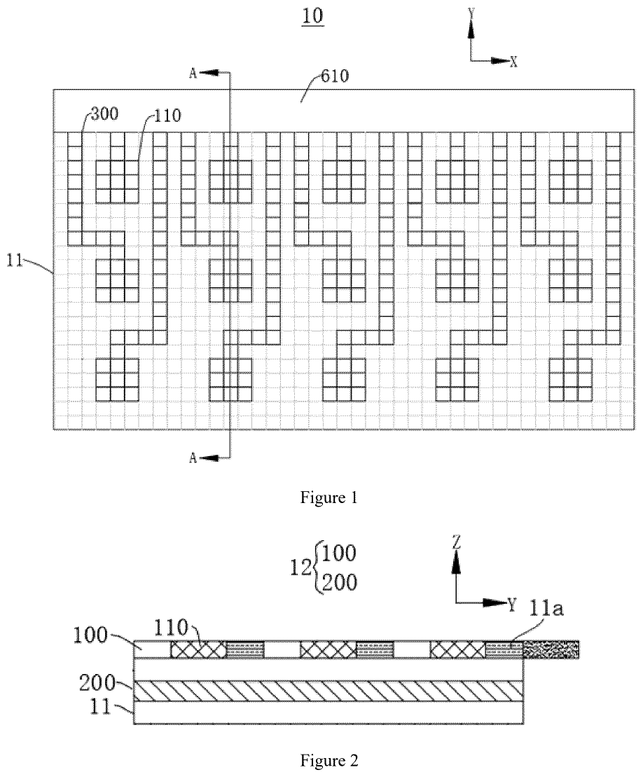

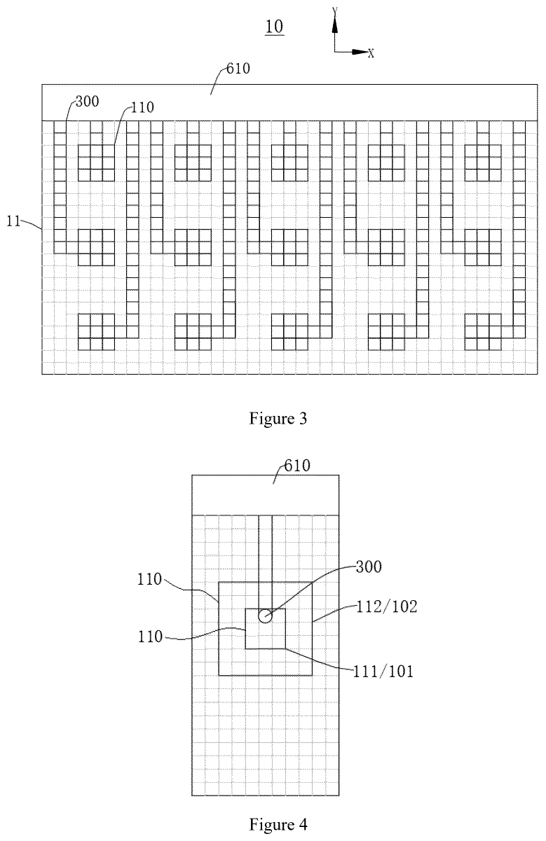

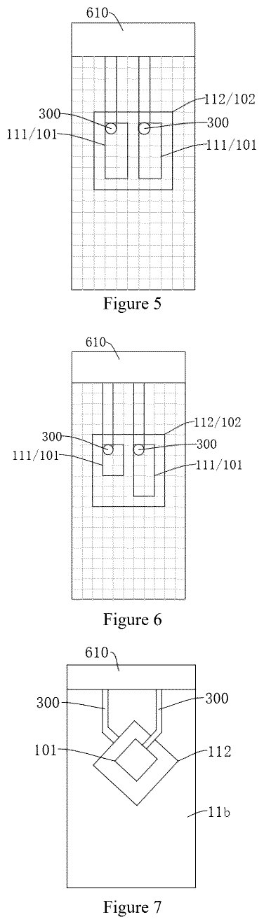

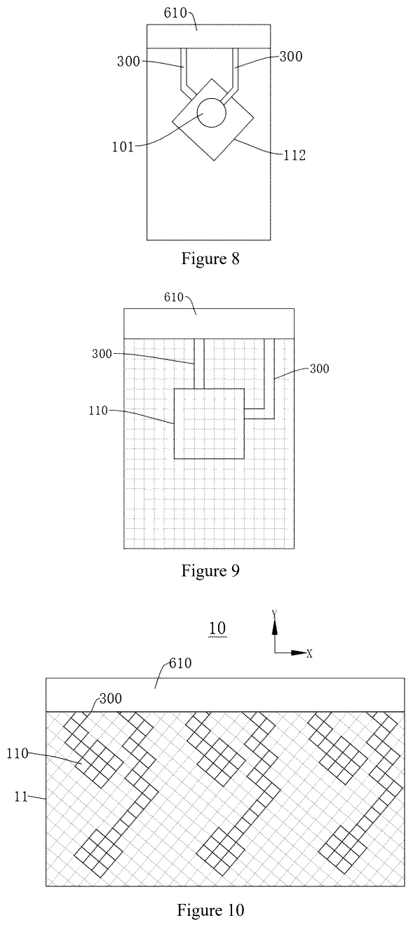

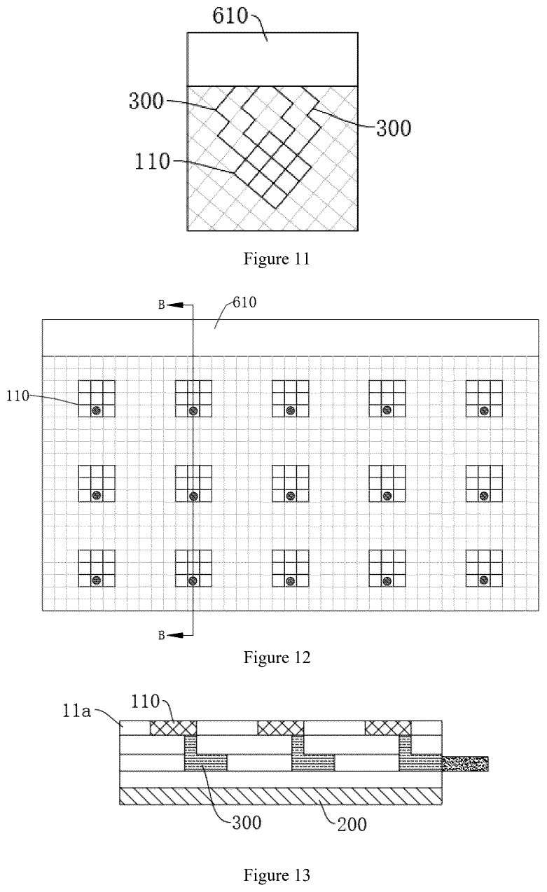

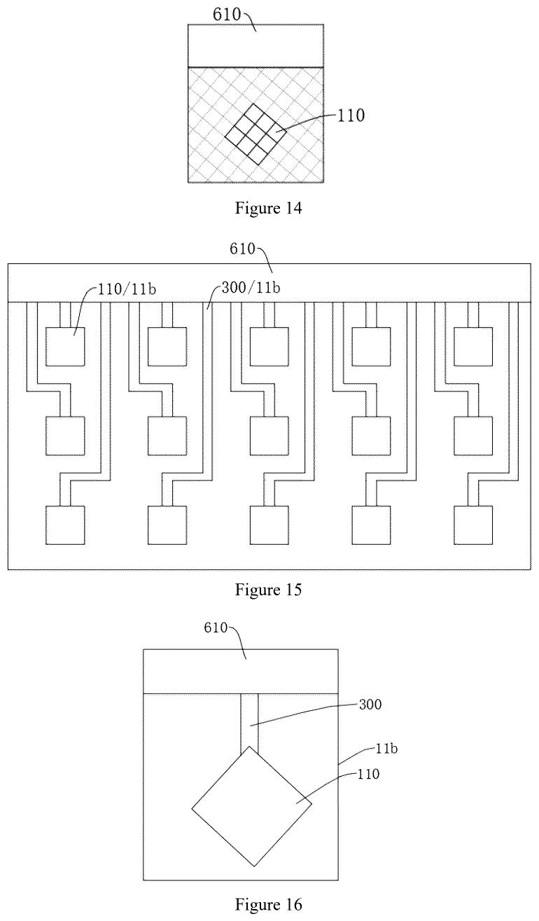

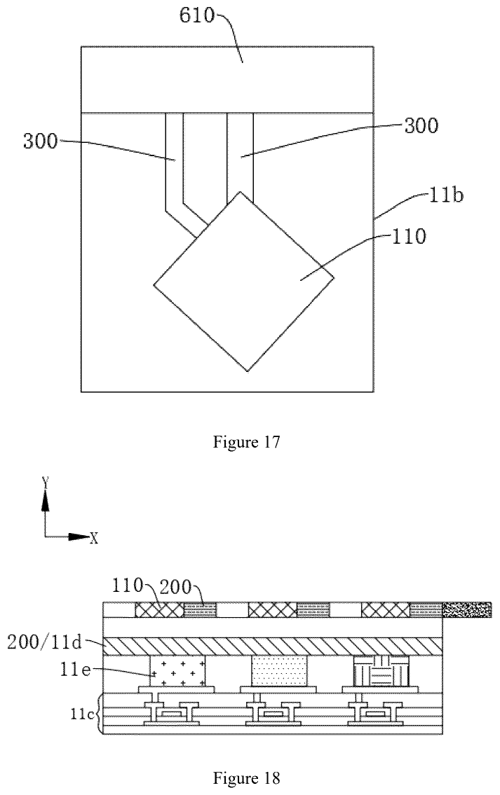

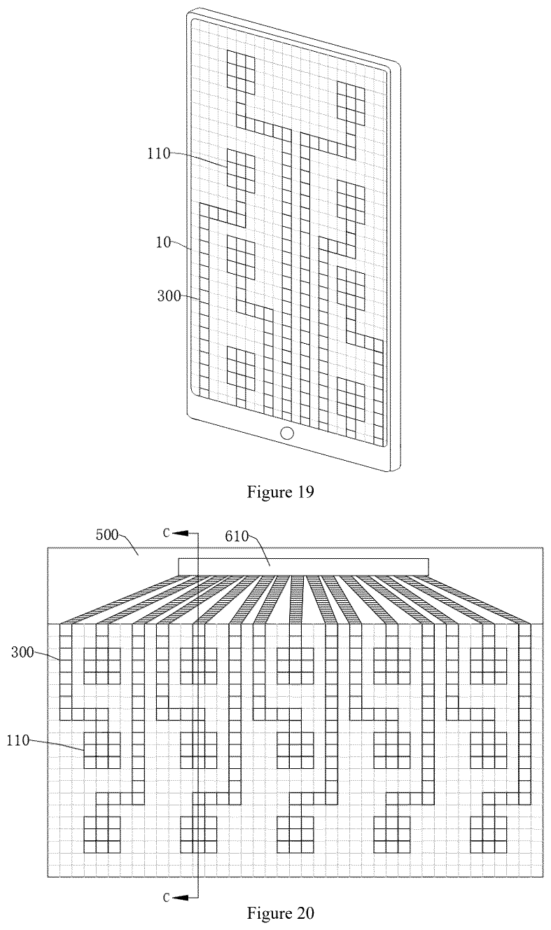

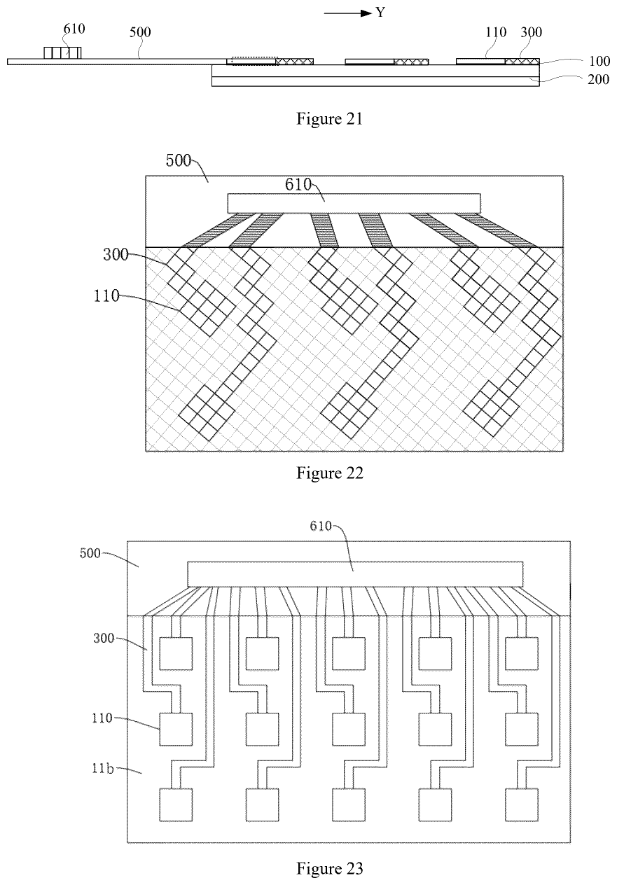

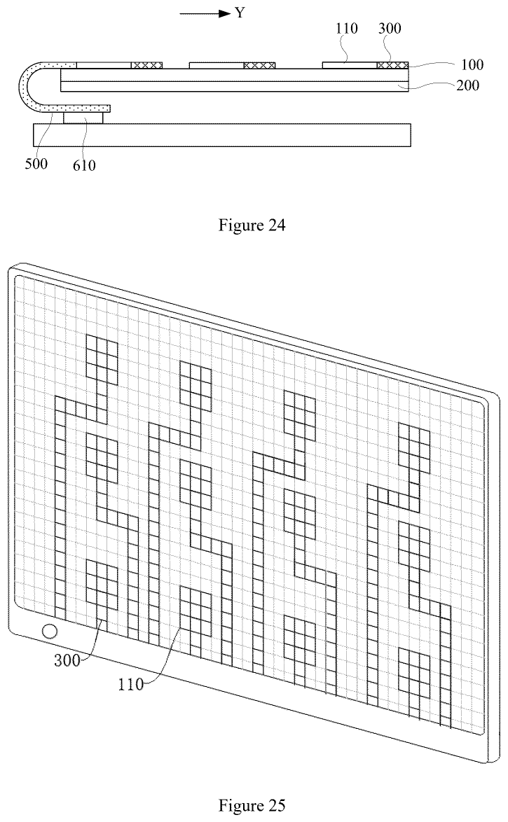

Referring to FIG. 1 and FIG. 2 together, FIG. 1 is a schematic diagram of a structure of a display panel 10 according to an embodiment of the present application, and FIG. 2 is a cross-sectional view taken along line A-A in FIG. 1.

As shown in FIG. 1 and FIG. 2, an embodiment of a first aspect of the present application provides a display panel 10. The display panel 10 includes a substrate 11 and a reflecting surface assembly 12. The reflecting surface assembly 12 is provided on the substrate 11, and the reflecting surface assembly 12 includes a functional layer 100 and a shielding layer 200. The functional layer 100 includes a reflecting unit 110, and the reflecting unit 110 is configured to reflect a wireless signal. The shielding layer 200 is provided on a side of the functional layer 100 facing the substrate 11. The reflecting unit 110 has a connection line 300 connected thereto such that the reflecting unit 110 is connectable to a control circuit 610 through the connection line 300. The control circuit 610 is configured to change an electrical load of the reflecting unit 110. Both the functional layer 100 and the shielding layer 200 are of a transparent layer structure.

In one embodiment, an overall light transmittance of the functional layer 100 and the shielding layer 200 is greater than 50%. In one embodiment, a light transmittance of the functional layer is greater than 60%, 70%, 80%, or even 90%. In one embodiment, a light transmittance of the shielding layer 200 is greater than 60%, 70%, 80%, or even 90%.

In the display panel 10 according to this embodiment of the present application, the display panel 10 includes the substrate 11 and the reflecting surface assembly 12 provided on the substrate 11. The reflecting surface assembly 12 includes the functional layer 100, the shielding layer 200, and the control circuit 610. The functional layer 100 includes the reflecting unit 110, and the reflecting unit 110 can reflect the wireless signal, for example, the reflecting unit 110 can reflect the wireless signal to a communication target, to improve the wireless communication quality of the display panel 10. The shielding layer 200 is provided on the side of the functional layer 100 facing away from a display surface of the display panel 10, such that the shielding layer 200 can shield the wireless signal to enable the wireless signal to be reflected at the functional layer 100, and can also reduce the entry of the wireless signal into the display panel 10 that affects normal operation of other parts and components of the display panel 10. The control circuit 610 is connected to the reflecting unit 110 through the connection line 300, and is configured to change the electrical load of the reflecting unit 110. Both the functional layer 100 and the shielding layer 200 are transparent structural layers, which can reduce the impact of the reflecting surface assembly 12 on the display effect of the display panel 10. Therefore, in the embodiments of the present application, providing the reflecting surface assembly 12 with high light transmittance in the display panel 10 can effectively improve the wireless communication performance of the display panel 10.

In one embodiment, the shielding layer 200 acts as a metal plate for the above-described IRS to shield and reflect the wireless signal.

The display panel 10 may be an organic light-emitting diode display panel, a liquid crystal display panel, or a micro light-emitting diode display panel.

In one embodiment, the functional layer 100 may be provided in a grid-patterned metal wiring layer. The structure of a grid-patterned metal wiring is shown with gray lines, and the reflecting unit 110 and the connection line 300 are shown with black lines in FIG. 1. In one embodiment, the grid-patterned metal wiring reused as the reflecting unit 110 and the connection line 300 is insulated from metal wires at other positions, to avoid a short-circuited connection between adjacent reflecting units 110. In one embodiment, the control circuit 610 is shown in FIG. 1, in which the connection line 300 is connected between the control circuit 610 and the reflecting unit 110. In other embodiments, the display panel 10 may not include the control circuit 610. For example, when the display panel 10 is used for the wireless communication apparatus, the wireless communication apparatus includes the control circuit 610.

In one embodiment, the functional layer 100 includes a plurality of reflecting units 110 distributed in an array, to improve the ability of the functional layer 100 to reflect wireless signals.

In one embodiment, each reflecting unit 110 is connected to at least one control circuit 610, and different reflecting units 110 are connected to different control circuits 610, enabling separate control of the respective reflecting units 110 through the respective control circuits 610.

In one embodiment, orthographic projections of two or more reflecting units 110 on the substrate 11 are within an orthographic projection of the shielding layer 200 on the substrate 11.

In one embodiment, referring to FIG. 1 and FIG. 3 together, FIG. 3 differs from FIG. 1 in the connection position between the connection line 300 and the reflecting unit 110. The connection line 300 may be connected to the reflecting unit 110 at various positions. An end portion of the connection line 300 that is connected to the reflecting unit 110 may be provided on any side in a peripheral direction of the reflecting unit 110, such that the connection line 300 can be connected to the reflecting unit 110, and then the reflecting unit 110 can be connected to the control circuit 610 through the connection line 300.

Different numbers of functional layers 100 may be provided. For example, as shown in FIG. 1 to FIG. 3, one functional layer 100 is provided, and two or more reflecting units 110 distributed in an array are provided within the functional layer 100. In one embodiment, one shielding layer 200 is provided.

In some other embodiments, as shown in FIG. 1 to FIG. 4, FIG. 4 is a partial enlarged view of the display panel 10. Two or more functional layers 100 may be provided. Providing the two or more functional layers 100 can further improve the reflecting ability.

In one embodiment, at least two reflecting units 110 located in different functional layers 100 have different areas of orthographic projections on the substrate 11. In one embodiment, FIG. 4 shows, on a top view, that two reflecting units 110 nested with each other are located in two different functional layers 100. Only one group of at least partially overlapping reflecting units 110 is shown in FIG. 4. In one embodiment, a plurality of groups of at least partially overlapping reflecting units 110 may be provided.

In these embodiments, two or more functional layers 100 are provided, and reflecting units 110 of different sizes are provided in different functional layers 100, such that the reflecting surface assembly 12 can reflect wireless signals in different frequency bands, to implement reflection of wireless signals in a plurality of frequency bands by the display panel, thereby further improving the wireless communication performance of the display panel 10.

In one embodiment, two or more reflecting units 110 in the same functional layer 100 have the same area of orthographic projections on the substrate 11, that is, the two or more reflecting units 110 in the same functional layer 100 have the same size, such that the two or more reflecting units 110 in the same functional layer 100 can reflect wireless signals in the same frequency band, thereby enhancing the ability to reflect the wireless signals in the same frequency band.

In some embodiments, still referring to FIG. 4, when two or more functional layers 100 are provided, the two or more functional layers 100 include a first functional layer 101 and a second functional layer 102, that is, one of the two or more functional layers 100 is the first functional layer 101, and the other is the second functional layer 102. The reflecting unit 110 includes a first reflecting unit 111 located in the first functional layer 101 and a second reflecting unit 112 located in the second functional layer 102. The first functional layer 101 is located on a side of the second functional layer 102 facing the display surface of the display panel 10, and an area of an orthographic projection of the first reflecting unit 111 on the substrate 11 is less than an area of an orthographic projection of the second reflecting unit 112 on the substrate 11.

In these embodiments, the first reflecting unit 111 is located on a side of the second reflecting unit 112 facing the display surface of the display panel 10, and a size of the first reflecting unit 111 is less than a size of the second reflecting unit 112. As such, at least part of the second reflecting unit 112 is not shielded by the first reflecting unit 111, and the second reflecting unit 112 can also reflect a wireless signal. In addition, since the size of the first reflecting unit 111 is different from the size of the second reflecting unit 112, wireless signals in a plurality of frequency bands can be reflected, such that the display panel 10 is able to regulate reflected signals for wireless signals in different frequency bands.

In one embodiment, an orthographic projection of each first reflecting unit 111 on the substrate 11 at least partially overlaps an orthographic projection of each second reflecting unit 112 on the substrate 11. As such, the overall distribution area of the two or more reflecting units 110 and thus the size of the reflecting surface assembly 12 can be reduced. The orthographic projection of each first reflecting unit 111 on the substrate 11 at least partially overlapping the orthographic projection of each second reflecting unit 112 on the substrate 11 includes: first reflecting units 111 being provided in a one-to-one correspondence with second reflecting units 112, and the orthographic projection of each first reflecting unit 111 on the substrate 11 at least partially overlapping the orthographic projection of each second reflecting unit 112 on the substrate 11; or two or more first reflecting units 111 being provided corresponding to the same second reflecting unit 112, or the same first reflecting unit 111 being provided corresponding to two or more second reflecting units 112, provided that the orthographic projection of each first reflecting unit 111 on the substrate 11 can at least partially overlap the orthographic projection of at least one second reflecting unit 112 on the substrate 11, or the orthographic projection of each second reflecting unit 112 on the substrate 11 can at least partially overlap the orthographic projection of at least one first reflecting unit 111 on the substrate 11.

In one embodiment, as shown in FIG. 4, at least part of the connection line 300 is provided in an overlapping area between the first reflecting unit 111 and the second reflecting unit 112 and is connected to the first reflecting unit 111 and the second reflecting unit 112.

In these embodiments, providing the at least part of the connection line 300 in the overlapping area between the first reflecting unit 111 and the second reflecting unit 112 and enabling the at least part of the connection line 300 to extend in the thickness direction of the display panel 10 to be connected to both the first reflecting unit 111 and the second reflecting unit 112 can simplify the structure of the connection line 300.

In one embodiment, as shown in FIG. 4, the first reflecting units 111 may be provided in a one-to-one correspondence with the second reflecting units 112. In one embodiment, as shown in FIG. 5, since the size of the first reflecting unit 111 is less than the size of the second reflecting unit 112, two or more first reflecting units 111 may be provided corresponding to the same second reflecting unit 112.

In some embodiments, as shown in FIG. 5, two or more first reflecting units 111 are provided corresponding to the same second reflecting unit 112, and in the corresponding second reflecting unit 112 and two or more first reflecting units 111, the orthographic projections of the two or more first reflecting units 111 on the substrate 11 are within the orthographic projection of the same second reflecting unit 112 on the substrate 11. Only one second reflecting unit 112 is shown in FIG. 5. In one embodiment, a plurality of second reflecting units 112 may be provided. The plurality of second reflecting units 112 are spaced apart from each other, and two or more first reflecting units 111 are provided on a side of each second reflecting unit 112 facing the display surface of the display panel 10.

In these embodiments, since the size of the first reflecting unit 111 is relatively small, providing the two or more first reflecting units 111 corresponding to the same second reflecting unit 112 can increase the number of first reflecting units 111 that can be provided, thereby improving the wireless communication performance of the first functional layer 101. The orthographic projections of the two or more first reflecting units 111 on the substrate 11 are within the orthographic projection of the same second reflecting unit 112 on the substrate 11, which makes the arrangement of the first reflecting units 111 and the second reflecting unit 112 more regular, thereby facilitating preparation and formation.

In one embodiment, as shown in FIG. 6, in the corresponding second reflecting unit 112 and two or more first reflecting units 111, the two or more first reflecting units 111 have different areas of orthographic projections on the substrate 11, such that the two or more first reflecting units 111 corresponding to the same second reflecting unit 112 can reflect wireless signals in different frequency bands, thereby further improving the wireless communication performance of the display panel 10.

In some other embodiments, as shown in FIG. 5, in the corresponding second reflecting unit 112 and two or more first reflecting units 111, the two or more first reflecting units 111 may also have the same area of orthographic projections on the substrate 11.

In one embodiment, as shown in FIG. 7 and FIG. 8, the orthographic projection of the first reflecting unit 111 on the substrate 11 and the orthographic projection of the second reflecting unit 112 on the substrate 11 may have the same or different shapes. For example, the orthographic projection of the second reflecting unit 112 on the substrate 11 has a rectangular shape, and the orthographic projection of the first reflecting unit 111 on the substrate 11 may have a rectangular or circular shape.

In one embodiment, in the embodiments shown in FIG. 7 and FIG. 8, the reflecting unit 110 and the connection line 300 may not be provided in the grid-patterned metal wiring layer. For example, the reflecting unit 110 and/or the connection line 300 is provided in a light-transmissive conductive layer.

In some embodiments, as shown in FIG. 1 to FIG. 8, the same reflecting unit 110 may be connected to the same control circuit 610, or the same reflecting unit 110 may be connected to two or more control circuits 610. Through the two or more control circuits 610, an electrical load of the reflecting unit 110 can be changed, and then amplitude adjustment, phase adjustment, etc. can be performed on the reflecting unit 110.

In one embodiment, when the same reflecting unit 110 is connected to two or more control circuits 610, as shown in FIG. 9, the same reflecting unit 110 has two or more connection lines 300 connected thereto, and the reflecting unit 110 is connected to the respective control circuits 610 through the respective connection lines 300. When the same reflecting unit 110 has two or more connection lines 300 connected thereto, the two or more connection lines 300 are spaced apart from each other on the same reflecting unit 110, to alleviate interference between the two or more connection lines 300.

Referring to FIG. 10 and FIG. 11, the reflecting unit 110 and/or the connection line 300 is provided in a grid-patterned metal wiring layer, and metal traces in the grid-patterned metal wiring layer have different extension directions from those in FIG. 1. In these embodiments, as shown in FIG. 10, the reflecting unit 110 may be connected to one connection line 300, or as shown in FIG. 11, the reflecting unit 110 may be connected to two or more connection lines 300.

In some embodiments, as shown in FIG. 1 and FIG. 2, the display panel 10 further includes a signal line layer 11a. The reflecting unit 110 and the connection line 300 may be provided in the same layer and both located in the signal line layer 11a, to simplify the structure of the display panel 10.

In one embodiment, as shown in FIG. 12 to FIG. 14, the reflecting unit 110 is provided in the signal line layer 11a, while the connection line 300 is provided in another conductive layer. Providing the reflecting unit 110 and the connection line 300 in different layers facilitates flexible layout of the reflecting unit 110 in the signal line layer 11a and flexible layout of the connection line 300 in the other conductive layer. In one embodiment, the connection line 300 is provided in the signal line layer 11a, while the reflecting unit 110 is provided in another conductive layer. This facilitates flexible arrangement of the connection line 300 in the signal line layer 11a and flexible arrangement of the reflecting unit 110 in the other conductive layer, enabling the arrangement of the reflecting unit 110 and the arrangement of the connection line 300 not to interfere with each other. In FIG. 12 and FIG. 14, since the reflecting unit 110 and the connection line 300 are provided in different layers, the reflecting unit 110 can be observed while the connection line 300 cannot be observed from the top view.

In one embodiment, the connection line 300 may be provided in a conductive layer on a side of the functional layer 100 facing away from the shielding layer 200. For example, the connection line 300 is provided in the signal line layer 11a, and the signal line layer 11a may be located on the side of the functional layer 100 facing away from the shielding layer 200. In one embodiment, as shown in FIG. 13, the connection line 300 may be provided in a conductive layer between the functional layer 100 and the shielding layer 200. In one embodiment, the connection line 300 is provided in the signal line layer 11a, and the signal line layer 11a may be located between the functional layer 100 and the shielding layer 200.

The signal line layer 11a may be provided in various ways. For example, as shown in FIG. 1 to FIG. 6, and FIG. 9 to FIG. 14, the signal line layer 11a includes a grid-patterned metal wiring, and at least part of the grid-patterned metal wiring is reused as the reflecting unit 110 and/or the connection line 300. The grid-patterned metal wiring includes a first signal line extending in a first direction X (a gray signal line extending in the first direction X in FIG. 1) and a second signal line extending in a second direction Y (a gray signal line extending in the second direction Y in FIG. 1). A plurality of first signal lines and a plurality of second signal lines intersect to form a grid pattern.

As described above, when a part of the grid-patterned metal wiring is reused as the reflecting unit 110 and/or the connection line 300, the part of the grid-patterned metal wiring is insulated from grid-patterned metal wirings at other positions, to avoid a short-circuited connection between adjacent reflecting units 110 and/or connection lines 300.

In one embodiment, as shown in FIG. 10, FIG. 11, and FIG. 14, an extension direction of the grid-patterned metal wiring intersects a length direction of the display panel 10. The extension direction of the grid-patterned metal wiring may be an extension direction of the first signal line, or may be an extension direction of the second signal line. The display panel 10 includes a first side edge and a second side edge, and two first side edges and two second side edges are alternately connected to enclose the display panel 10. A length of the first side edge is greater than a length of the second side edge, and an extension direction of the first side edge may be the length direction of the display panel 10. The extension direction of the grid-patterned metal wiring intersecting the length direction of the display panel 10 means the extension direction of the first signal line and/or the second signal line intersecting the extension direction of the first side edge, which can reduce the impact of the grid-patterned metal wiring on the display effect of the display panel 10.

In some other embodiments, as shown in FIG. 7, FIG. 8, and FIG. 15 to FIG. 17, the display panel 10 further includes a light-transmissive conductive layer 11b. A material of the light-transmissive conductive layer 11b includes a light-transmissive conductive material such as indium tin oxide, to improve the light transmittance of the light-transmissive conductive layer 11b. The light-transmissive conductive layer 11b has the characteristics of high light transmittance and conducting electricity.

In one embodiment, at least one of the reflecting unit 110, the connection line 300, and the shielding layer 200 is provided in the light-transmissive conductive layer 11b, to improve the light transmission performance of the reflecting surface assembly 12 and reduce the impact of the reflecting surface assembly 12 on the display effect of the display panel 10.

In one embodiment, the light-transmissive conductive layer 11b includes a first conductive layer (not shown in the figure) and a second conductive layer (not shown in the figure) that are stacked. At least one of the reflecting unit 110 and the connection line 300 is provided in the first conductive layer, and the shielding layer 200 is provided in the second conductive layer. In these embodiments, the connection line 300 and the shielding layer 200 are both provided in the light-transmissive conductive layer 11b, and are located in different conductive layers, which can alleviate interference between the arrangement of the connection line 300 and the arrangement of the shielding layer 200, and can also ensure the light transmittance of the reflecting surface assembly 12.

In one embodiment, when the reflecting unit 110 and/or the connection line 300 is provided in the light-transmissive conductive layer 11b, as shown in FIG. 16, the reflecting unit 110 may have one connection line 300 connected thereto; or as shown in FIG. 17, the reflecting unit 110 may have two or more connection lines 300 connected thereto.

In some embodiments, as shown in FIG. 18, the substrate 11 includes an array substrate 11c and a common electrode layer 11d. The common electrode layer 11d is located on a side of the array substrate 11c facing the display surface of the display panel 10, that is, the common electrode layer 11d is located on a side of the array substrate 11c facing the reflecting surface assembly. The reflecting unit 110 is located on a side of the common electrode layer 11d facing away from the array substrate 11c. The common electrode layer 11d is reused as the shielding layer 200. Enabling an original layer structure of the display panel 10 to be reused as the shielding layer 200 can simplify the structure of the display panel 10.

In one embodiment, the array substrate 11c includes a base substrate and a drive circuit provided on the base substrate. In one embodiment, a planarization layer, a pixel electrode layer, and a pixel definition layer are provided on the substrate 11. The pixel electrode layer includes a plurality of pixel electrodes distributed in an array on the planarization layer, and the pixel definition layer is located on a side of the pixel electrode layer facing away from the planarization layer. The pixel definition layer includes a pixel defining portion and a pixel opening enclosed by the pixel defining portion, and a light-emitting unit 11e may be provided in the pixel opening. The common electrode layer 11d is provided on a side of the pixel defining portion and the light-emitting unit 11e facing away from the planarization layer.

In one embodiment, an encapsulation layer and a touch layer are further provided on a side of the common electrode layer 11d facing away from the pixel definition layer, and the reflecting unit 110 may be provided in the touch layer, to further simplify the structure of the display panel 10.

As shown in FIG. 19 to FIG. 25, an embodiment of a second aspect of the present application further provides a wireless communication apparatus, including a display panel 10 according to any one of the above-described embodiments of the first aspect. Since the wireless communication apparatus according to the present application includes the display panel 10 according to the above-described embodiment, the wireless communication apparatus according to the embodiment of the present application has the beneficial effects of the display panel 10 according to any one of the above-described embodiments, which will not be repeated herein.

The wireless communication apparatus in this embodiment of the present application includes, but is not limited to, devices having a display function, such as a mobile phone, a wireless wearable device, a personal digital assistant (PDA), a tablet computer, an e-book reader, a television, an access control system, a smart fixed-line telephone, a console, an electronic display board, or a display board with a transparent base substrate.

As shown in FIG. 20 and FIG. 22, the reflecting unit 110 and/or the connection line 300 of the display panel 10 may be provided in the grid-patterned metal wiring layer. FIG. 20 differs from FIG. 22 in the extension direction of metal traces in the grid-patterned metal wiring layer. In one embodiment, as shown in FIG. 23, the reflecting unit 110 and/or the connection line 300 of the display panel 10 may be provided in the light-transmissive conductive layer 11b.

In some embodiments, as shown in FIG. 21 and FIG. 25, the wireless communication apparatus further includes a circuit board 500. The circuit board 500 may be a flexible circuit board. The control circuit 610 is provided on the circuit board 500, and the circuit board 500 is bent such that the control circuit 610 is located on a non-display side of the display panel 10. As such, the proportion of the display area on the wireless communication apparatus can be increased. FIG. 21 is a schematic diagram of a structure of the circuit board 500 in an unfolded state. FIG. 24 is a schematic diagram of a structure of the circuit board 500 in a folded state.

An embodiment of a third aspect of the present application further provides a reflecting surface assembly, including a functional layer 100 and a shielding layer 200. The functional layer 100 includes a reflecting unit 110, and the reflecting unit 110 is configured to reflect a wireless signal. The shielding layer 200 is provided on a side of the functional layer 100. The reflecting unit 110 has a connection line 300 connected thereto such that the reflecting unit 110 is connectable to a control circuit 610 through the connection line 300, and the control circuit 610 is configured to change an electrical load of the reflecting unit 110. Both the functional layer 100 and the shielding layer 200 are of a transparent layer structure.

In this embodiment of the present application, since the functional layer 100 and the shielding layer 200 are of a transparent layer structure, the light transmittance of the entire reflecting surface assembly can be improved, making the reflecting surface assembly applicable to the display panel, etc.

In one embodiment, the functional layer 100 and the shielding layer 200 of the reflecting surface assembly are provided as described above, and details will not be repeated herein.

Although the present application has been described with reference to embodiments, various modifications can be made, and components can be replaced with equivalents, without departing from the scope of the present application. In particular, the embodiments can be combined in any manner, provided that there is no structural conflict. The present application is not limited to the embodiments disclosed herein but includes all the embodiments that fall within the scope of the claims.

1. A display panel, comprising:
a substrate; and
a reflecting surface assembly provided on the substrate, the reflecting surface assembly comprising a functional layer and a shielding layer, the functional layer comprising at least a reflecting unit configured to reflect wireless signals, and the shielding layer being provided on a side of the functional layer facing the substrate, wherein the reflecting unit has a connection line connected thereto, wherein the reflecting unit is connectable to a control circuit through the connection line, and the control circuit is configured to change an electrical load of the reflecting unit; and
wherein both the functional layer and the shielding layer are transparent layer structures.

2. The display panel according to claim 1, wherein the functional layer comprises two or more reflecting units distributed in an array.

3. The display panel according to claim 2, wherein two or more functional layers are provided.

4. The display panel according to claim 3, wherein at least two reflecting units located in different functional layers have different areas of orthographic projections on the substrate.

5. The display panel according to claim 3, wherein the two or more functional layers comprise a first functional layer and a second functional layer, and the reflecting unit comprises a first reflecting unit located in the first functional layer and a second reflecting unit located in the second functional layer, wherein the second functional layer is located on a side of the first functional layer facing the substrate, and an area of an orthographic projection of the first reflecting unit on the substrate is less than an area of an orthographic projection of the second reflecting unit on the substrate.

6. The display panel according to claim 5, wherein an orthographic projection of at least one first reflecting unit on the substrate at least partially overlaps an orthographic projection of at least one second reflecting unit on the substrate.

7. The display panel according to claim 6, wherein at least part of the connection line is provided in an overlapping area between the first reflecting unit and the second reflecting unit and is connected to the first reflecting unit and the second reflecting unit.

8. The display panel according to claim 3, wherein first reflecting units are provided in a one-to-one correspondence with second reflecting units, and an orthographic projection of each first reflecting unit on the substrate is within an orthographic projection of each second reflecting unit on the substrate.

9. The display panel according to claim 3, wherein two or more first reflecting units are provided corresponding to the same second reflecting unit, and in the corresponding second reflecting unit and two or more first reflecting units, orthographic projections of the two or more first reflecting units on the substrate are within an orthographic projection of the same second reflecting unit on the substrate.

10. The display panel according to claim 9, wherein in the corresponding second reflecting unit and two or more first reflecting units, the two or more first reflecting units have different areas of orthographic projections on the substrate.

11. The display panel according to claim 1, further comprising a signal line layer, wherein the reflecting unit and/or at least part of the connection line is provided in the signal line layer.

12. The display panel according to claim 11, wherein the signal line layer is a touch signal line layer and comprises a grid-patterned metal wiring, and at least part of the grid-patterned metal wiring is reused as the reflecting unit and/or at least part of the connection line.

13. The display panel according to claim 11, wherein at least part of the connection line and the reflecting unit are both provided in the signal line layer.

14. The display panel according to claim 11, wherein the signal line layer is provided between the functional layer and the shielding layer, at least part of the connection line is provided in the signal line layer, and the reflecting surface assembly further comprises a connection portion that connects the reflecting unit and the connection line;
or the signal line layer is provided on a side of the functional layer facing away from the shielding layer, at least part of the connection line is provided in the signal line layer, and the reflecting surface assembly further comprises a connection portion that connects the reflecting unit and the connection line.

15. The display panel according to claim 1, further comprising a light-transmissive conductive layer, wherein at least one of the reflecting unit, the connection line, and the shielding layer is provided in the light-transmissive conductive layer.

16. The display panel according to claim 15, wherein the light-transmissive conductive layer comprises a first conductive layer and a second conductive layer that are stacked, at least one of the reflecting unit and the connection line is provided in the first conductive layer, and the shielding layer is provided in the second conductive layer.

17. The display panel according to claim 1, wherein the substrate comprises an array substrate and a common electrode layer located on a side of the array substrate facing the reflecting surface assembly, wherein the reflecting unit is provided on a side of the common electrode layer facing away from the array substrate, and the common electrode layer is reused as the shielding layer.

18. A wireless communication apparatus, comprising a display panel according to any one of claims 1.

19. The wireless communication apparatus according to claim 18, further comprising a flexible circuit board, wherein the control circuit is provided on the flexible circuit board, and the flexible circuit board is bent, wherein the control circuit is located on a non-display side of the display panel.

20. A reflecting surface assembly, comprising a functional layer and a shielding layer, the functional layer comprising at least a reflecting unit configured to reflect wireless signals, and the shielding layer being provided on a side of the functional layer, wherein the reflecting unit has a connection line connected thereto, wherein the reflecting unit is connectable to a control circuit through the connection line, and the control circuit is configured to change an electrical load of the reflecting unit; and
wherein both the functional layer and the shielding layer are of a transparent layer structure.
